(19) United States
(12) Patent Application Publication
(10) Pub. No.: US 2005/0276093 A1
(43) Pub. Date: Dec. 15, 2005

(54) Memory cell, memory cell arrangement, patterning arrangement, and method for fabricating a memory cell

(75) Inventors: Andrew Graham, Munich (DE); Franz Hofmann, Munich (DE); Wolfgang Honlein, Unterhaching (DE); Johannes Kretz, Munich (DE); Franz Kreupl, Munich (DE); Erhard Landgraf, Munich (DE); Richard J. Luyken, Munich (DE); Wolfgang Roesner, Ottobrunn (DE); Thomas Schulz, Austin, TX (US); Michael Specht, Munich (DE)

Correspondence Address: DARBY & DARBY P.C., P. O. BOX 5257, NEW YORK, NY, 10150-5257, US

(73) Assignee: Infineon Technologies AG, Munich (DE)

(21) Appl. No.: 11/119,531

(22) Filed: Apr. 29, 2005

Related U.S. Application Data
(63) Continuation of application No. PCT/DE03/03589, filed on Oct. 29, 2003.

(30) Foreign Application Priority Data
Oct. 31, 2002 (DE) 102 50 834.8

(51) Int. Cl. G11C 11/24

(52) U.S. Cl. 365/149

(57) ABSTRACT

A memory cell having a storage capacitor and a vertical switching transistorm, which has a semiconducting nanostructure which has grown on at least part of the storage capacitor and includes a semiconducting nanotube, a bundle of semiconducting nanotubes, or a semiconducting nanorod.

### CROSS-REFERENCE TO RELATED APPLICATION

This application is a continuation of International Patent Application Serial No. PCT/DE2003/003589, filed Oct. 29, 2003, which published in German on May 13, 2004 as WO 2004/040644, and is incorporated herein by reference in its entirety.

### FIELD OF THE INVENTION

The invention relates to a memory cell, a memory cell arrangement, a patterning arrangement and a method for fabricating a memory cell.

### BACKGROUND OF THE INVENTION

On account of rapid development in computer technology, ever greater quantities of data need to be stored. For silicon microtechnology, this means the need for ongoing miniaturization increases the integration density of a semiconductor memory in a semiconductor substrate.

One important concept in the development of semiconductor memories is the concept of the DRAM (dynamic random access memory) memory cell. A DRAM is a dynamic semiconductor memory which, as memory cell, has one capacitor per bit in its memory matrix. The binary storage of information is effected by charging this capacitor. A memory cell is addressed via a switching transistor which couples the capacitor to a bit line. To read or program the memory cell, the word line is brought to a sufficiently high electrical potential, so that the switching transistor becomes conductive and the memory cell is coupled to the bit line. During programming, the capacitor is charged or discharged depending on the memory information items to be stored (logic 0 or 1). When reading the information, the stored charge on the bit line generates a voltage change which can be detected and is a characteristic measure of the information item stored in the memory cell.

On account of the low capacitance of the storage transistor of a memory cell and on account of inevitable losses of current, it is necessary to periodically refresh the charge contents of the capacitor.

A DRAM memory cell is usually designed as an integrated semiconductor circuit. When developing a DRAM memory arrangement with increasingly small dimensions, i.e. with ever greater storage densities, the problem arises that the size of each component of a DRAM memory cell in each dimension is at least the value F, F being the minimum feature size which can be achieved in a particular technology generation. Moreover, the storage capacitor is difficult to scale. This restricts the extent to which DRAM memory cells can be miniaturized.

A further important concept in semiconductor memories is what is known as the FRAM (ferroelectric random access memory) concept.

According to one implementation, an FRAM memory cell is an MOS field-effect transistor in which a ferroelectric layer is provided instead of the gate-insulating layer. A preferential direction for the permanent ferroelectric dipole moments in the ferroelectric layer is defined, i.e. the FRAM memory cell is programmed, by means of a suitably selected gate voltage. The electrical conductivity of the channel region adjoining the ferroelectric layer is influenced in a characteristic way as a function of what preferential direction for the ferroelectric dipoles has been set in the ferroelectric layer as a result of previous programming by application of a suitable gate voltage. In other words, the intensity of the electric current between the two source/drain regions between which the channel region is arranged depends on the state of the ferroelectric dipoles of the ferroelectric layer as a result of a preceding programming event.

According to an alternative concept for an FRAM memory cell, the same structure as in the DRAM memory cell described above is used, with the exception that a ferroelectric (e.g. lead zirconate titanate, Pb(Zr₁₋ₓTiₓ)O₃, PZT) is used instead of a dielectric between the capacitor electrodes. It can be concluded from the hystersis curve of a ferroelectric that the ferroelectric has a positive or negative permanent polarization depending on whether a positive or negative field strength (or voltage) is applied during programming. The memory cell is read by the application of a positive voltage to the bit line. If the ferroelectric has a negative polarization, the polarization is reversed, so that a charge packet flows to the bit line. If the permanent polarization is positive, the polarization changes only slightly, and consequently scarcely any charge flows to the bit line.

The problem described above in connection with the DRAM memory cell whereby the minimum feature size which can be achieved is limited by the minimum one-dimensional feature resolution F which can be achieved within a particular semiconductor technology generation also arises when forming an FRAM memory cell.

Furthermore, with increasing miniaturization of a conventional semiconductor memory cell based on a MOSFET, the problem arises whereby in particular the length of the conducting channel decreases as a result, leading to disruptive short-channel effects. Therefore, conventional concepts for an integrated memory cell are increasingly encountering fundamental physical problems.

Nanotubes, in particular carbon nanotubes, are considered one possible successor to conventional semiconductor electronics. By way of example, Harris, P. J. F. (1999) “Carbon Nanotubes and Related Structures—New Materials for the Twenty-first Century.”, Cambridge University Press, Cambridge, pp. 1 to 15, 111 to 155, provides an overview of this technology.

A carbon nanotube is a single-walled or multiwalled tube-like carbon compound. In the case of a multiwalled nanotube, at least one inner nanotube is coaxially surrounded by an outer nanotube. Single-walled nanotubes typically have diameters of approximately 1 nm, whereas the length of a nanotube may be several hundred nm. The ends of a nanotube are often closed off by means of in each case half a fullerene molecule. Nanotubes often have a good electrical conductivity, which makes nanotubes suitable for constructing circuits with dimensions in the nanometer range. On account of the electrical conductivity of nanotubes and on account of the possibility of adjusting this conductivity (for example by applying an external electric field or by doping the nanotube with boron nitride), nanotubes are suitable for a wide range of applications, for example for electrical coupling in integrated circuits, for components used in microelectronics and as electron emitters.

In addition to carbon nanotubes, nanotubes made from other materials, for example tungsten sulfide and other chalcogenides, are also known.

As well as nanotubes, nanostructures in the form of nanorods are also known. Nanorods likewise have a diameter in the nanometer range and may be several micrometers long. Typical materials for nanorods are the semiconductors silicon, germanium, indium phosphide and gallium arsenide.

Both nanotubes and nanorods can be deposited from the vapor phase by means of catalytic processes. An overview of the technology of nanostructures is given, for example, by Roth, S. (2001) “Leuchtdioden aus Nanostäcbchen”, [Light-emitting diodes formed by nanorods], Physikalische Blätter 57(3):17-18.

It is known from Suh, J. S., Lee, J. S. (1999) “Highly ordered two-dimensional carbon nanotube arrays” Applied Physical Letters 75(14): 2047-2049, and Lee, J. S., Gu, G. H., Kim, H., Jeong, K. S., Bae, J., Suh, J. S. (2001) “Growth of Carbon Nanotubes on Anodic Aluminum Oxide Templates: Fabrication of a Tube-in-Tube and Linearly Joint Tube” Chem. Mater. 13(7): 2387-2388, that highly ordered, two-dimensional patterns of carbon nanotubes can be grown in an aluminum oxide template. A substrate made from aluminum oxide with a two-dimensional arrangement of hexagonal pores is used for this purpose, which pores serve as a template for the growth of carbon nanotubes. In accordance with the process described in Suh et al. and Lee et al., cobalt is deposited in the pores as a catalyst for the growth of nanotubes on the base layer. Subsequently, carbon nanotubes are grown in the pores by the introduction of acetylene, with both aluminum and cobalt catalytically assisting the growth.

It is known from DE 100 36 897 C1 to introduce a through-hole into a thick gate electrode layer and to grow a vertical nanoelement in this hole. This produces a vertical field-effect transistor with the nanoelement as channel region, it being possible to control the electrical conductivity of the channel region by means of the gate electrode region that surrounds the nanoelement approximately along its entire longitudinal extent.

DE 198 05 076 A1 discloses a method for fabricating a semiconductor component, in which a copolymer triple block is formed with a first copolymer as inner column, a second copolymer as outer column and a third copolymer surrounding the second copolymer.

DE 100 36 897 C1 discloses a field-effect transistor, a circuit arrangement and a method for fabricating a field-effect transistor, in which a vertical nanoelement forms a channel of the field-effect transistor.

### SUMMARY OF THE INVENTION

The invention is based on the problem of providing a memory cell having a storage capacitor, which memory cell can be fabricated in miniaturized form, and in which memory cell short-channel effects are avoided in a field-effect transistor contained in the memory cell.

The problem is solved by a memory cell, a memory cell arrangement, a patterning arrangement and a method for fabricating a memory cell.

The invention provides a memory cell having a vertical switching transistor and a storage capacitor; the vertical switching transistor having a semiconducting nanostructure which has grown on at least part of the storage capacitor.

Furthermore, the invention provides a memory cell arrangement having a plurality of memory cells having the features described above.

Furthermore, the invention provides a method for fabricating a memory cell, in which a vertical switching transistor and a storage capacitor are formed; a semiconducting nanostructure of the vertical switching transistor which has grown on at least part of the storage capacitor being formed.

### BRIEF DESCRIPTION OF THE DRAWINGS

Exemplary embodiments are illustrated in the figures and explained in more detail below.

In the drawings:

FIGS. 1A to 1M show cross-sectional views through layer sequences at various times during a method for fabricating a memory cell in accordance with a first exemplary embodiment of the invention;

FIG. 1N shows a cross-sectional view, taken on section line A-A from FIG. 1M, of a layer sequence at a further time during the method for fabricating a memory cell in accordance with the first exemplary embodiment of the invention;

FIG. 1O shows a cross-sectional view, taken on section line A-A from FIG. 1M, of a memory cell in accordance with a preferred exemplary embodiment of the invention;

FIG. 2A shows a cross-sectional view of a layer sequence in accordance with an alternative configuration of the method according to the invention for fabricating a memory cell;

FIG. 2B shows a cross-sectional view of a patterning arrangement in accordance with a preferred exemplary embodiment of the invention;

FIG. 2C shows a cross-sectional view of a layer sequence, taken on a section line B-B from FIG. 2B, explaining the functionality of the patterning arrangement illustrated in FIG. 2B;

FIGS. 3A to 3F show cross-sectional views through layer sequences at different times during a method for fabricating a memory cell in accordance with a second exemplary embodiment of the invention;

FIG. 4 shows a cross-sectional view through a memory cell in accordance with another exemplary embodiment of the invention.

### DETAILED DESCRIPTION OF PREFERRED EMBODIMENTS OF THE INVENTION

The invention provides a memory cell having a vertical switching transistor and a storage capacitor; the vertical switching transistor having a semiconducting nanostructure which has grown on at least part of the storage capacitor.

Furthermore, the invention provides a memory cell arrangement having a plurality of memory cells having the features described above.

Furthermore, the invention provides a method for fabricating a memory cell, in which a vertical switching transistor and a storage capacitor are formed; a semiconducting nanostructure of the vertical switching transistor which has grown on at least part of the storage capacitor being formed.

The invention also provides a patterning arrangement having a nanostructure which extends substantially orthogonally with respect to the surface of a substrate and is arranged at least partially outside the substrate; having material that is to be patterned on the part of the nanostructure which is arranged outside the substrate; having an etchant feed device, which is designed in such a manner that it can be used to direct etchant for etching material that is to be patterned onto the nanostructure covered with material that is to be patterned at a predetermined angle with respect to the nanostructure, in such a manner that only those subregions of the material to be patterned which are in the shadow of the nanostructure with respect to the etchant are protected from being removed as a result of the etching.

The memory cell according to the invention can clearly be used as a DRAM memory cell or as an FRAM memory cell. The vertical switching transistor can be used to select a memory cell of the invention in a memory cell arrangement, so that the information stored in the storage capacitor can be read or programmed. The vertical switching transistor has a semiconducting nanostructure, for example a carbon nanotube, a carbon-nitrogen nanotube or a carbon-boron-nitrogen nanotube. The memory cell according to the invention can be fabricated in miniaturized form by using a nanostructure in the vertical switching transistor. By way of example, a vertical carbon nanotube which can be used as nanostructure has a dimension in cross section of one or a few nanometers, so that in principle it is possible in accordance with the invention to form a memory cell which only takes up this order of magnitude of space. Since the switching transistor having the semiconducting nanostructure is formed as a vertical transistor, it is simultaneously possible to effect miniaturization while avoiding short-channel effects. In its configuration as a carbon nanotube, the nanostructure may have an extent of hundreds of nanometers or even 1 μm in the vertical direction, and therefore the channel region as part of the nanostructure can be made sufficiently long to avoid disruptive short-channel effects.

It is preferable for the vertical switching transistor and the storage capacitor to be formed at least partially in and/or at least partially on a substrate.

The substrate is preferably a semiconductor substrate and in particular a silicon substrate.

The nanostructure may extend substantially orthogonally with respect to the surface of the substrate. It is preferable for a first end portion of the nanostructure to be arranged within the substrate and for a second end portion of the nanostructure to be arranged outside the substrate.

As a result of a subregion of the nanostructure being formed vertically outside the substrate, it is possible for this part of the nanostructure to serve as a “template” for the formation and in particular the selective removal of material on the nanostructure and/or on the substrate. Clearly, by way of example, an etchant can be directed onto the nanostructure and the substrate at a predetermined angle, with that region on the nanotube or on the substrate which is in the shadow of the nanotube with respect to the etchant being protected from etching. With this idea according to the invention, it is possible to form a wide range of structures in semiconductor technology.

It is preferable for the vertical switching transistor to be a field-effect transistor. In this case, the first portion of the nanostructure may form a first source/drain region, the second end portion of the nanostructure may form a second source/drain region and an intermediate region of the nanostructure, arranged between the two end portions, may form a channel region of the vertical switching transistor.

Furthermore, a dielectric layer may be formed between the first end portion of the nanostructure and the substrate, the first end portion of the nanostructure forming a first electrically conductive capacitor element, the dielectric layer forming a capacitor dielectric and the substrate forming a second electrically conductive capacitor element of the storage capacitor.

According to this design, the nanostructure performs the function both of a component of the vertical switching transistor and of a first conductive capacitor element of the storage capacitor. The first electrically conductive capacitor element of the storage capacitor configured as an integrated component is the analog of a capacitor plate of a conventional capacitor. By virtue of the nanostructure performing a dual function, as a component of the vertical switching transistor and of the capacitor element, electrical contact-connection is simplified and there is no need for a separate element, and consequently the memory cell according to the invention can be fabricated with a low level of outlay.

A layer of a ferroelectric material may be provided instead of the dielectric layer. According to this configuration, the memory cell according to the invention can be used as an FRAM memory cell having the functionality described above.

Catalyst material for catalyzing the formation of the nanostructure may be arranged between at least a part of the dielectric layer and the nanostructure.

It is possible to predetermine the spatial growth of the nanostructures by means of the catalyst material. Therefore, the provision of an ordered arrangement of regions of catalyst material, which are not necessarily cohesive, makes it possible to allow ordered growth of the nanostructure. It should be noted that in particular if the nanostructure is designed as a carbon nanotube, iron, cobalt or nickel is a good choice of catalyst material.

Furthermore, at least part of the intermediate region of the nanostructure may be surrounded by an electrically insulating ring structure which forms the gate insulation layer of the vertical transistor, and at least part of the electrically insulating ring structure may be surrounded by a first electrically conductive region which forms the gate electrode of the vertical switching transistor and the word line.

Since the semiconducting nanostructure is surrounded by an electrically insulating ring structure in the vicinity of its intermediate region, a gate insulating layer which is surrounded by the first electrically conductive region functioning as gate electrode is provided. The conductivity of the nanostructure can be influenced in a characteristic way in the intermediate region of the nanostructure, functioning as channel region, as a result of the application of a suitable voltage to the electrically conductive region, so that the nanostructure together with the electrically insulating ring structure and the first electrically conductive region performs the functionality of a field-effect transistor. On account of an electrostatic peak effect, the amplitude of an electric field generated by the application of an electric voltage to the gate electrode can be made particularly high in the vicinity of the nanostructure by the use of an annular gate electrode, so that particularly accurate control of the electrical conductivity of the channel region is possible.

It should be noted that the vertically grown nanostructure can also function as a shadow mask for the formation of the first electrically conductive region. Therefore, the components mentioned are formed by means of a self-aligning process, allowing these components to be formed with a low level of outlay.

It is preferable for the second end portion of the nanotube to be surrounded by a second electrically conductive region which forms the bit line. The nanostructure also functions as a shadow mask during the formation of the bit line, as described in more detail below.

The semiconducting nanostructure may include a semiconducting nanotube, a bundle of semiconducting nanotubes or a semiconducting nanorod. A semiconducting nanostructure formed as a nanorod may include silicon, germanium, indium phosphide and/or gallium arsenide. If the nanostructure is formed as a semiconducting nanotube, this may be a semiconducting carbon nanotube, a semiconducting carbon-boron nanotube or a semiconducting carbon-nitrogen nanotube.

The memory cell may be formed exclusively from dielectric material, metallic material and the material of the nanostructure. The substrate may consist of polycrystalline or amorphous material.

In other words, the memory cell according to the invention may consist only of electrically conductive material, dielectric material and material of the nanostructure (preferably a carbon nanotube) . In this case, the memory cell can be fabricated without the need for expensive semiconductor technology processes. A further important advantage in this context is that a polycrystalline or amorphous material, i.e. a material which is not in single-crystal form, can be used as substrate for fabrication of the memory cell. This avoids the need for an expensive single-crystal substrate (for example a silicon wafer) in the fabrication of the memory cell. According to the invention, in principle any desired starting substrate can be used.

The memory cell arrangement according to the invention, which has a plurality of memory cells according to the invention, preferably in an arrangement substantially in matrix form, is a memory cell arrangement with a particularly high integration density. Configurations of the memory cell also apply to the memory cell arrangement.

The text which follows describes the method according to the invention for producing a memory cell. Configurations of the memory cell also apply to the method for fabricating the memory cell.

According to one refinement of the method according to the invention for fabricating a memory cell, the vertical switching transistor and the storage capacitor are formed at least partially in and/or on a substrate.

The nanostructure may be formed substantially orthogonally with respect to the surface of the substrate.

A first end portion of the nanostructure may be formed within the substrate, and a second end portion of the nanostructure may be formed outside the substrate.

The first end portion of the nanostructure may preferably be formed as a first source/drain region, the second end portion of the nanostructure may preferably be formed as a second source/drain region, and an intermediate region of the nanostructure arranged between the two end portions may preferably be formed as a channel region of the vertical switching transistor, which is designed as a field-effect transistor.

A dielectric layer may be formed between the first end portion of the nanostructure and the substrate, the first end portion of the nanostructure being formed as a first electrically conductive capacitor element, the dielectric layer being formed as a capacitor dielectric and the substrate being formed as a second electrically conductive capacitor element of the storage capacitor.

In the method, catalyst material for catalyzing the formation of the nanostructure may be formed at least between part of the dielectric layer and the nanostructure.

Furthermore, at least part of the intermediate region of the nanostructure may be surrounded by an electrically insulating ring structure which forms the gate insulation layer of the vertical transistor, and at least part of the electrically insulating ring structure may be surrounded by a first electrically conductive region which forms the gate electrode of the vertical switching transistor and the word line.

The second end portion of the nanotube may be surrounded by a second electrically conductive region, which forms the bit line.

In particular, the word line and/or the bit line and/or the gate electrode may be formed by a part of the nanostructure which is uncovered or covered with a layer being covered with electrically conductive material and an etchant for etching the electrically conductive material being directed onto the nanostructure covered with the electrically conductive material at a predetermined angle with respect to the nanostructure, in such a manner that only those subregions of the electrically conductive material which are in the shadow of the nanostructure with respect to the etchant are protected from being removed as a result of the etching.

The method according to the invention described in particular has the advantage that the number of lithography steps required to form the memory cell is reduced compared to the prior art. This is based, inter alia, on the fact that the vertically oriented nanostructure can be used as a shadow mask during directional etching of various layers, in particular when forming word and bit lines or when forming the electrically insulating ring structure as a gate insulating layer.

It is possible in the manner described to obtain a DRAM memory cell which takes up an area of just 4F² on a substrate, F being the minimum feature size which can be achieved for a particular technology generation. This increases the integration density compared to the prior art. Furthermore, on account of the vertical arrangement of the memory cell according to the invention, it is possible for a plurality of layers of memory cells to be arranged stacked on top of one another, in order thereby to achieve three-dimensional integration of memory cells, which further increases the integration density. It should be noted in particular that the concept of the invention can also be used to form an FRAM memory cell. For this purpose, the dielectric layer of the capacitor dielectric is to be formed from a ferroelectric material.

The DRAM/FRAM concept of the invention has the advantages of allowing self-aligning, stacked formation of the vertical switching transistor on the storage capacitor, that the memory cell can be formed on a substrate which is not necessarily crystalline silicon, that the memory cell arrangement of the invention can be stacked in three dimensions, that the area taken up by a memory cell on the surface of a substrate is reduced to 4F², that it is possible to produce the memory cell according to the invention by means of a single lithographic method step (cf. description below), that it is possible to realize a transistor architecture with an annular gate insulating region, with all the gate electrodes automatically being coupled so as to form a self-aligning word line.

One basic concept of the invention is that the growth of the nanostructure can be realized in an etched trench, which serves as a template for the growth, using the CVD (chemical vapor deposition) process, it being possible to define a seed position for the growth of nanotubes in three dimensions by means of the targeted application of catalyst material. A further aspect of the invention is that of using a nanostructure as an electrically conductive element of an integrated capacitor. Another aspect is based on the use of a vertical transistor having a nanostructure. A further aspect is the growth of a nanostructure with a high aspect ratio and the use of this nanostructure as a shadow mask (i.e. evidently as an auxiliary structure) for forming the annular transistor gate (gate insulating layer and gate electrode) and for forming word and bit lines. A further aspect of the invention is that a vertically oriented nanostructure can be used for the self-aligned, stacked formation of integrated components, for example of a storage capacitor and a vertical switching transistor in a DRAM or FRAM memory cell.

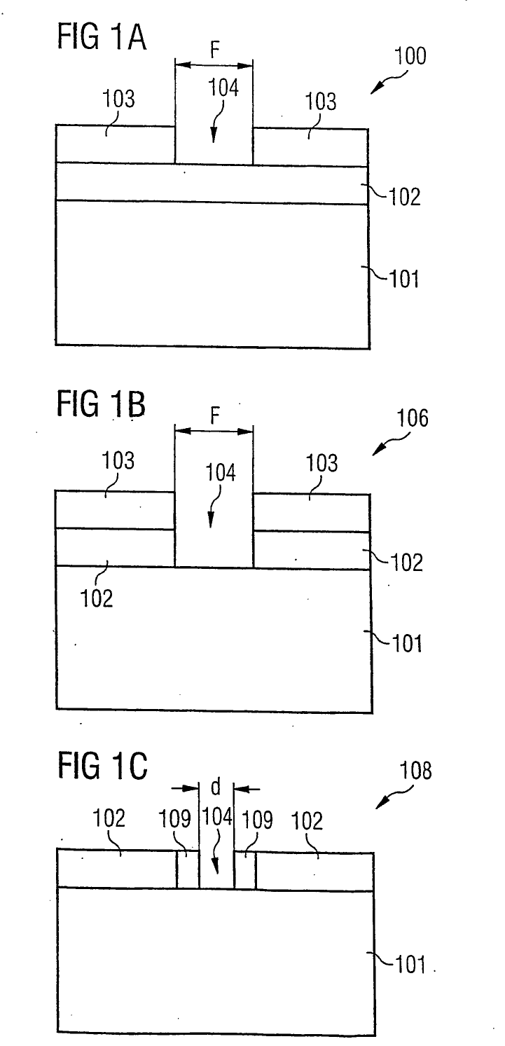

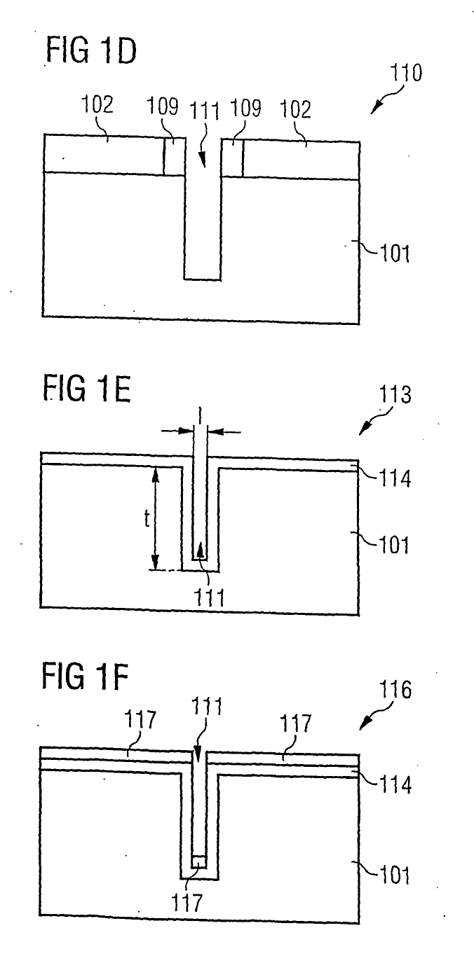

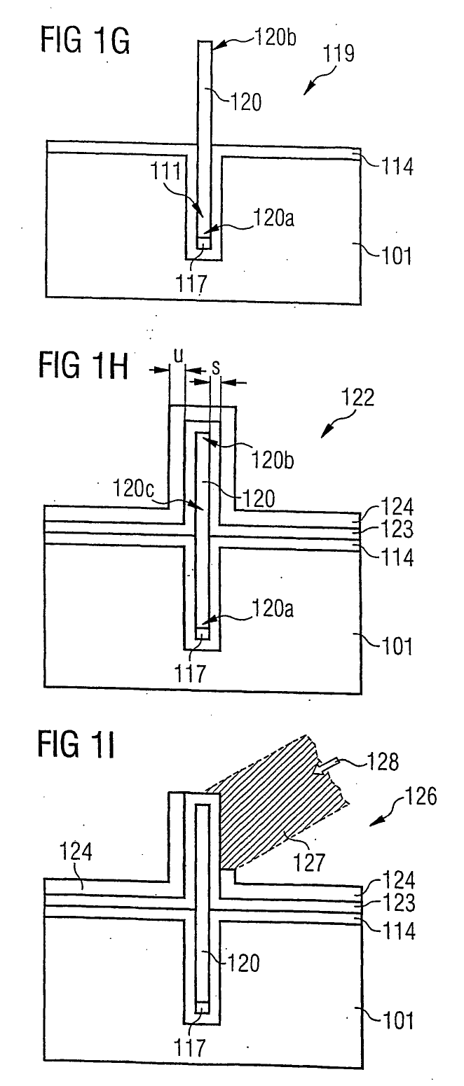

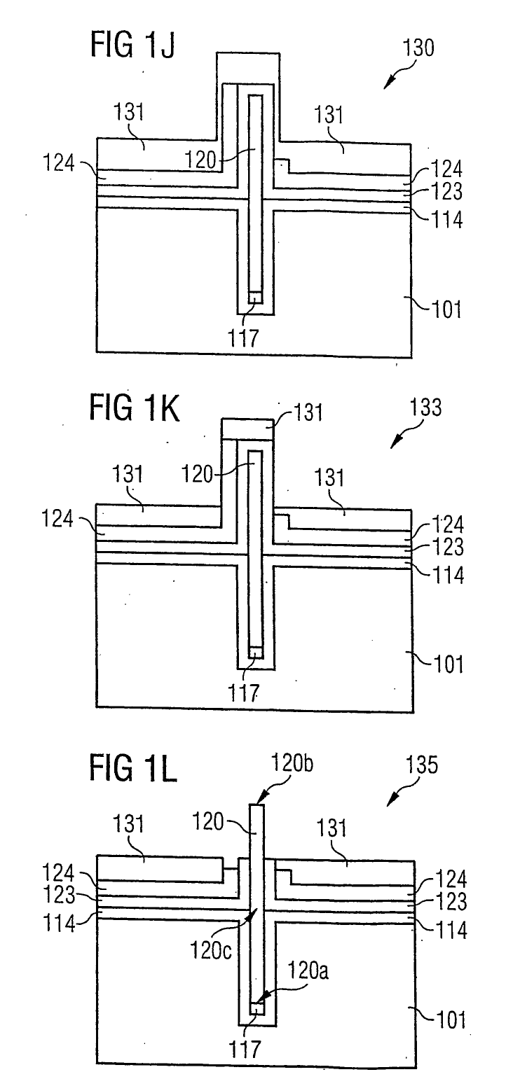

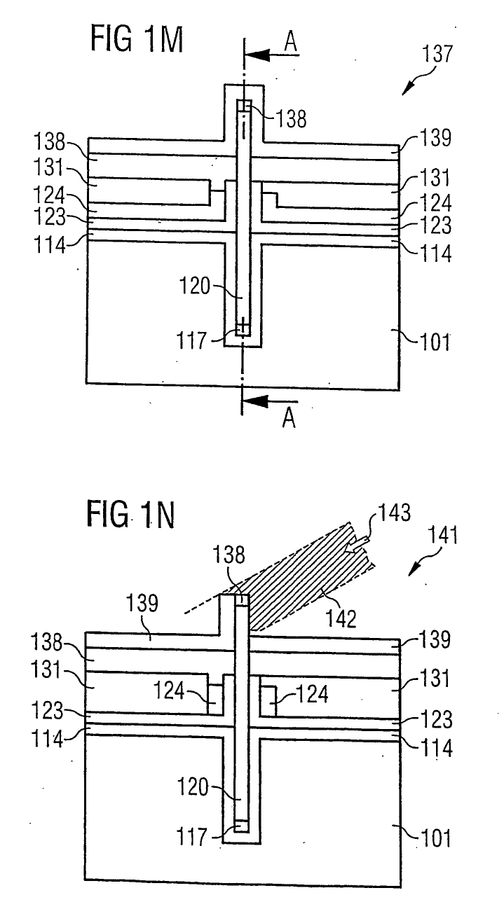

The following text, referring to FIG. 1A to FIG. 1O, describes a method for fabricating a memory cell in accordance with a first exemplary embodiment of the invention.

To obtain the layer sequence 100 shown in FIG. 1A, a silicon nitride hard mask 102 is deposited on a doped silicon substrate 101, and a photoresist layer 103 is deposited on the silicon nitride hard mask 102 and patterned using a lithography process and an etching process, so that a patterning window 104 is formed on the surface of the layer sequence 100. As an alternative to the exemplary embodiment described, it would be possible for an additional silicon dioxide layer (not shown in the figures) to be deposited between the doped silicon substrate 101 and the silicon nitride hard mask 102, for example in order to separate the top side of a capacitor that is subsequently to be formed and the transistor that is subsequently to be formed. The doped silicon substrate 101 is optionally made from crystalline or polycrystalline silicon material.

To obtain the layer sequence 106 shown in FIG. 1B, that part of the silicon nitride hard mask 102 which has been uncovered in the patterning window 104 is removed using an anisotropic etching process. As shown in FIG. 1A, FIG. 1B, the patterning window 104 has a lateral width F, F representing the minimum feature size which can be achieved in a particular technology generation.

To obtain the layer sequence 108 shown in FIG. 1C, regions 109 which narrow the patterning window are introduced into the patterning window 104. As a result, the lateral width of the uncovered surface of the doped silicon substrate 101 is reduced to a width d, which is selected to be such that the uncovered surface region of the doped silicon substrate 101 has a suitable area for the induction of a nanostructure. In other words, the region 109 which narrows the structuring window is only required if the value F of the lithography resolution available is significantly larger than an appropriate lateral width of a trench into which a nanostructure is to be introduced in a subsequent method step. Typical nanostructure diameters (for example for carbon nanotubes) are in a range from approximately 1 nm to 10 nm. Therefore, a significantly larger minimum patterning feature size F should be scaled down to a smaller value using the regions 109 which narrow the patterning window, in order to obtain a suitably dimensioned trench in a further method step. The dimension d is typically of the order of magnitude of a few tens of nm.

To obtain the layer sequence 110 shown in FIG. 1D, a trench 111 is etched into the doped silicon substrate 101 using a suitable etching process. The lateral extent of the trench is defined by means of the regions 109 which narrow the patterning window or by means of the patterning window 104 itself. In a further, optional method step, the dopant concentration in the doped silicon substrate 101 can be increased further by the introduction of further doping atoms into the (pre-)doped silicon substrate 101, for example using an ion implantation process or a diffusion process, in order to increase the capacitance of a capacitor that is to be formed in subsequent method steps.

To obtain the layer sequence 113 shown in FIG. 1E, the silicon nitride hard mask 102 and the regions 109 which narrow the patterning window (and which according to the exemplary embodiment described are also produced from silicon nitride material) are removed using a suitable etching process. Furthermore, a dielectric layer 114 is deposited conformally on the surface of the layer sequence using a CVD (chemical vapor deposition) process or using an ALD (atomic layer deposition) process. In a scenario in which the memory cell that is fabricated is to be used as an FRAM memory cell, a ferroelectric layer is deposited instead of a dielectric layer 114. It is preferable for the thickness of the dielectric layer 114 to be set to approximately 10 nm, so that the lateral width of the trench 111 has an extent l of approximately 10 nm after the dielectric layer 114 has been formed. Furthermore, it should be noted that the depth t of the trench 111 is set to be such that the capacitance of the DRAM storage capacitor that is to be formed subsequently does not drop below approximately 20 fF. Clearly, the dependent relationship between the capacitance of the storage capacitor and the depth t is attributable to the fact that the capacitance proportional to the capacitor plate surface area is greater the longer the region of the dielectric layer between the doped silicon substrate 101 and a nanostructure which is subsequently to be introduced into the trench 111, i.e. the greater the depth t. A value in the region of 1 μm is typically selected for t. Furthermore, it should be noted that the trench 111 may be partially filled with doped polysilicon after the dielectric layer 114 has been formed, in order to achieve a particularly high capacitance of the storage capacitor.

To obtain the layer sequence 116 shown in FIG. 1F, iron material 117 as catalyst material for catalyzing the formation of carbon nanotubes is formed on part of the dielectric layer 114.

To obtain the layer sequence 119 shown in FIG. 1G, first of all iron material 117 is removed from the surface of the layer sequence 116, with the exception of the region contained in the trench 111, using an angle-selective etching process. Then, a carbon nanotube 120 is grown orthogonally with respect to the surface of the doped silicon substrate 101, in such a manner that a first end portion 120a is arranged within the doped silicon substrate 101 and that a second end portion 120b of the carbon nanotube 120a is arranged outside the doped silicon substrate 101. The growth of the carbon nanotube 120 takes place using a CVD process by introduction of acetylene or methane into the process chamber. Alternatively, it is also possible for nanotubes of carbon and nitrogen or of carbon, nitrogen and boron to be used as carbon nanotubes 120. It is also possible to use doped nanotubes, or for nanotubes to be doped in an additional method step. By setting the method parameters, it is possible to control the length of the carbon nanotube 120. In particular, it is possible to establish a uniform growth length of the nanotubes when forming a plurality of carbon nanotubes in different surface regions of a layer sequence. Furthermore, it should be noted that the growth of the carbon nanotube 120 takes place selectively on the iron material 117, with the trench 111 serving as a template or as a guide for growth. This ensures that vertical carbon nanotubes 120 are formed. The aspect ratio can be set by setting the length of the carbon nanotube 120 in the vertical direction in accordance with FIG. 1G. Alternatively, the length of the carbon nanotube 120 can be controlled by a silicon dioxide layer, the thickness of which corresponds to the desired thickness of the carbon nanotube region outside the substrate 101, being applied to the layer sequence 119 having the carbon nanotube that has already been formed and this silicon dioxide layer being planarized using a CMP (chemical mechanical polishing) process, and by the silicon dioxide layer being removed by means of a subsequent selective etching process. Furthermore, this time in the method is an appropriate one for the optional doping of the carbon nanotube in order to set the transistor and/or capacitor properties.

To obtain the layer sequence 122 shown in FIG. 1H, an intermediate region 120c of the carbon nanotube 120 and a second end portion 120b of the carbon nanotube 120 and also the partial region of the dielectric layer 114 which is arranged on the surface of the layer sequence 119 are covered with a first silicon dioxide layer 123, which first silicon dioxide layer 123 subsequently forms the gate-insulating layer of the vertical switching transistor that is to be formed. This deposition is carried out using a CVD process or an ALD process. The thickness s of the conformally deposited first silicon dioxide layer 123 is approximately 5 nm. Furthermore, an electrically conductive first titanium nitride layer 124 is deposited conformally on the surface of the layer sequence in a thickness u of between approximately 10 nm and 30 nm using an ALD process. Alternatively, it is also possible for tungsten rather than titanium nitride to be used as material for this layer; this tungsten can be deposited using an ALD process or a CVD process. It is also possible to use PVD metals if they can be deposited conformally. In further method steps, the first titanium nitride layer 124 is processed in such a manner as to form a word line for a DRAM memory cell.

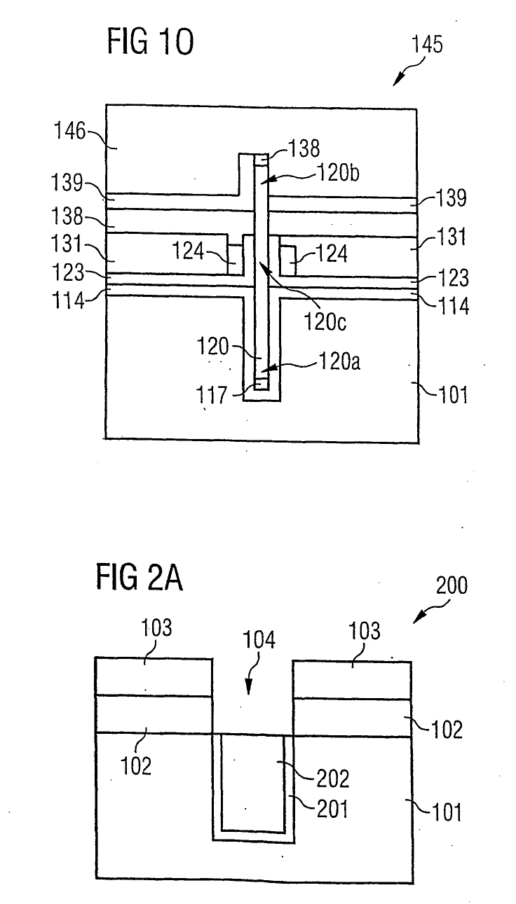

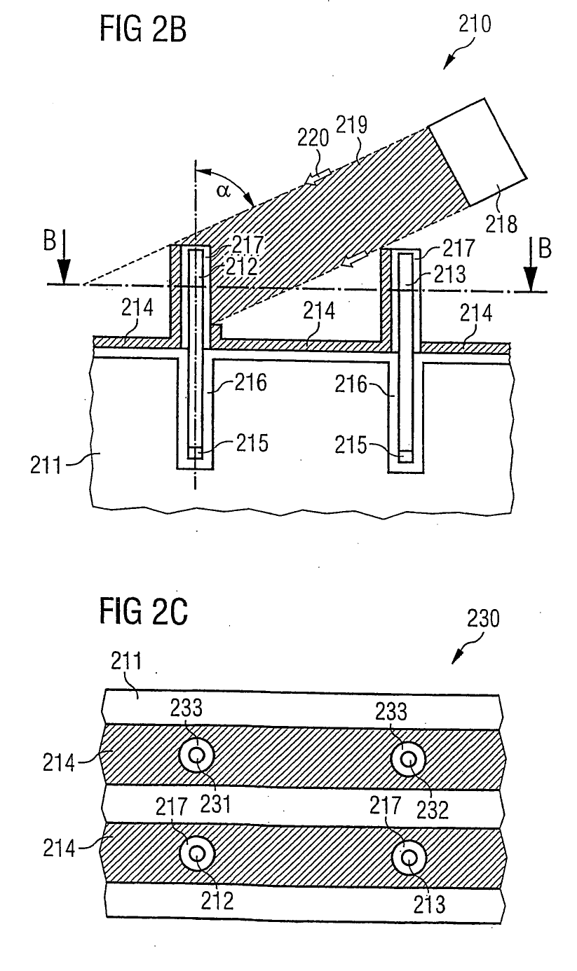

To obtain the layer sequence 126 shown in FIG. 1I, the first titanium nitride layer 124 is partially removed from the surface of the layer sequence 122, with the subregion of the first titanium nitride layer 124 which is removed in this method step being defined by an etchant for the selective etching of titanium nitride material being directed onto the layer sequence 122 at an angle which is such that only a desired subregion of the first titanium nitride layer 124 is attacked by the etchant, whereas another subregion of the first titanium nitride layer 124 is protected from etching, since the carbon nanotube 120 (and/or further vertical carbon nanotubes, not shown in FIG. 1I, on adjacent surface regions of the substrate 101) shadow surface regions of the substrate 101 with respect to the etchant. The region of the surface of the layer sequence which is attacked by the etchant is denoted by reference numeral 127 in FIG. 1I. Furthermore, the direction in which the etchant for the selective ion etching of the first titanium nitride layer 124 is directed onto the layer sequence 122 is indicated as arrow 128 in FIG. 1I. As a result of the method step described, the subsequent word line or the subsequent gate electrode of the vertical switching transistor is formed by virtue of that part of the carbon nanotube 120 which is covered with the silicon dioxide layer 123 being covered with the first titanium nitride layer 124 and an etchant for etching the first titanium nitride layer 124 being directed onto the carbon nanotube 120 covered by the first titanium nitride layer 124 at a predeterminable angle with respect to the carbon nanotube 120, in such a manner that only those subregions of the first titanium nitride layer 124 which are in the shadow of the carbon nanotube 120 with respect to the etchant are protected against being removed as a result of the etching. It should be noted that this method step can be carried out using the patterning arrangement according to the invention, which is described below with reference to FIGS. 2B, 2C. The carbon nanotube 120 which is covered with the silicon dioxide layer 123 and the first titanium nitride layer 124 evidently serves as a shadow mask for the formation of the word lines. The spatial extent of the conformally deposited first titanium nitride layer 124 on the carbon nanotube 120 ensures that the word line has a greater spatial extent that the carbon nanotube 120 and the dielectric silicon dioxide layer 123, with all the gate electrodes of memory cells on a substrate being coupled to one another by means of the word line. Furthermore, a ring-like structure can be formed around the carbon nanotube 120 as gate electrode.

To obtain the layer sequence 130 shown in FIG. 1J, a second silicon dioxide layer 131 is applied directionally to the layer sequence 126 using a sputtering process. Alternatively, the second silicon dioxide layer 131 can be applied using the spin-on glass process.

To obtain the layer sequence 133 shown in FIG. 1K, the second silicon dioxide layer 131 is partially removed or etched back using a conformal etching process. The result of this is that the thickness of the second silicon dioxide layer 131 is lower in FIG. 1K than in FIG. 1J, and that after the method step the side walls of the vertical arrangement made up of carbon nanotube 120, first silicon dioxide layer 123 and first titanium nitride layer 124 are devoid of coverage by the second silicon dioxide layer 131.

To obtain the layer sequence 135 shown in FIG. 1L, the first titanium nitride layer 124 and the first silicon dioxide layer 123 are etched back using a selective etching process in such a manner that the second end portion 120b of the carbon nanotube 120 is uncovered. This method step also removes a subregion of the second silicon dioxide layer 131.

To obtain the layer sequence 137 shown in FIG. 1M, a third silicon dioxide layer 138 is deposited in targeted form as intermetal dielectric on the layer sequence 135 using a sputtering process and partially etched back selectively, in order to clean the carbon nanotube 120. Furthermore, a second titanium nitride layer 139 is deposited conformally on the surface of the layer sequence obtained in this way, with a bit line being formed from the second titanium nitride layer 139 in a subsequent method step.

The further method steps involved in forming the memory cell according to the invention are described with reference to FIG. 1N, FIG. 1O. The cross-sectional views of the layer sequence shown in those figures are taken on section line A-A shown in FIG. 1M.

In a similar way to in the method step involved in the transition from FIG. 1H to FIG. 1I, a directional, angle-selective etching process using an etchant for etching the second titanium nitride layer 139 is used to obtain the layer sequence 141 shown in FIG. 1N. For this purpose, etchant is directed onto the layer sequence 137 from the side, at a predeterminable angle with respect to the carbon nanotube 120, in the direction 143 shown in FIG. 1N; on account of the carbon nanotube 120 functioning as a shadow mask, the region 142 which is attacked by the etchant is such that only a subregion of the second titanium nitride layer 139 is removed from the surface of the layer sequence 137. As a result, cohesive bit lines are formed. This method step is clearly similar to the method step carried out at the transition from FIG. 1H to FIG. 1I, during which the word lines were formed, but the patterning arrangement used to carry out this method step is oriented differently with respect to the layer sequence.

To obtain the memory cell 145 shown in FIG. 1O, a fourth silicon dioxide layer 146 is applied to the layer sequence 141 as a covering layer, for example using a CVD process.

The text which follows describes the functionality of the memory cell 145 shown in FIG. 1O in accordance with a preferred exemplary embodiment of the invention.

The memory cell 145 has a vertical switching transistor and a storage capacitor, the vertical switching transistor including the semiconducting carbon nanotube 120 which has been grown on part of the storage capacitor. The vertical switching transistor and the storage capacitor are arranged partially in and partially on the doped silicon substrate 101. The first end portion 120a of the carbon nanotube 120 is arranged within the doped silicon substrate 101, and the second end portion 120b of the carbon nanotube 120 is arranged outside the substrate 101. The vertical switching transistor is designed as a field-effect transistor, with the first source/drain region of the vertical transistor, designed as a field-effect transistor, being the first end portion 120a of the carbon nanotube 120, the second end portion 120b of the carbon nanotube forming the second source/drain region of the vertical switching transistor, and the intermediate region 120c, arranged between the two end portions 120a, 120b, of the carbon nanotube 120 forming the channel region of the vertical switching transistor. The intermediate region 120c of the carbon nanotube 120 is surrounded by an electrically insulating ring structure, formed by the first silicon dioxide layer 123, which forms the gate insulating layer of the vertical switching transistor. That region of the first silicon dioxide layer 123 which forms the electrically insulating ring structure is surrounded by the first titanium nitride layer 124, which forms the gate electrode of the vertical switching transistor and the word line. The second end portion 120b of the carbon nanotube 120 is partially surrounded by the electrically conductive second titanium nitride layer 139, which forms the bit line of the memory cell. The storage capacitor of the memory cell 145 is formed by two electrically conductive capacitor elements (which in the integrated stacked capacitor form the analog of the capacitor plates of a conventional capacitor) and by a dielectric layer as capacitor dielectric between the two electrically conductive capacitor elements. The first end portion 120a of the carbon nanotube 120 forms the first electrically conductive capacitor element, the doped silicon substrate 101 forms the second electrically conductive capacitor element, and the subregion of the dielectric layer 114 which separates the first end portion 120a of the carbon nanotube 120 from the doped silicon substrate 101 forms the capacitor dielectric.

The conductivity of the carbon nanotube 120, in particular in the intermediate region 120c, is influenced in a characteristic way, on account of the field effect, by the application of a suitable voltage to the first titanium nitride layer 124, which functions as a word line, and consequently by applying a suitable voltage to the first titanium nitride layer 124 it is possible to select the memory cell 145 shown in FIG. 1O in a memory cell arrangement having a plurality of memory cells. According to the invention, the ring-like structure of gate electrode and gate insulating layer allows particularly good driving control. To program the memory cell 145, when the vertical switching transistor is in a conducting state electric charge is programmed into the stacked capacitor via the second titanium nitride layer 139, which is formed as a bit line.

The presence of electric charge in the storage capacitor can be interpreted as a state with a logic 1, whereas a state in which there is no electric charge stored in the storage capacitor can be interpreted as a logic 0. If the information stored in the memory cell 145 is to be read, the vertical switching transistor is brought into a conducting state by the application of a suitable voltage to the word line 124, so that any charge carriers which may be stored in the storage capacitor flow onto the bit line 139, where a corresponding electrical signal can be detected. This signal is characteristic of the information stored in the storage capacitor.

The following text, referring to FIG. 2A, describes an alternative configuration of the method according to the invention for fabricating a memory cell.

Starting from the layer sequence 106 shown in FIG. 1B (or alternatively starting from the layer sequence 108 shown in FIG. 1C), it is possible, as shown in FIG. 2A, to form the storage capacitor by first of all etching a trench into the doped silicon substrate 101 of the layer sequence 106, by lining this trench with a silicon dioxide dielectric 201 by means of thermal oxidation of the doped silicon substrate 101 or by means of depositing silicon dioxide material at the walls of the trench, and by filling the resulting trench with doped polycrystalline silicon material 202. This results in the layer sequence 200 shown in FIG. 2A. According to this scenario, the storage capacitor of the memory cell according to the invention is formed by the doped silicon substrate 101 and the doped polysilicon material 202 as first and second electrically conductive capacitor elements and by the silicon dioxide dielectric 201 as capacitor dielectric. In this case, a carbon nanotube which is subsequently to be applied only has the function of acting as the switching transistor of the memory cell. The further method steps involved in forming the memory cell, starting from the layer sequence 200, are carried out analogously to the steps described in FIG. 1C to FIG. 1O.

The following text describes a preferred exemplary embodiment of the patterning arrangement according to the invention with reference to FIGS. 2B, 2C.

The patterning arrangement 210 has first and second carbon nanotubes 212, 213, which extend substantially orthogonally with respect to the surface of a substrate 211 and are arranged partly outside the substrate 211. Furthermore, the patterning arrangement includes material 214 that is to be patterned on that part of the carbon nanotubes 212, 213 which is arranged outside the substrate 211. Furthermore, the patterning arrangement 210 may include further layers 215, 216, 217, by which the first and second carbon nanotubes 212, 213 may be partially surrounded. Furthermore, the patterning arrangement 210 has an etchant feed device 218, which is designed in such a manner that it can be used to direct etchant for etching material 214 that is to be patterned onto the carbon nanotubes 212, 213 covered with material 214 that is to be patterned at a predeterminable angle α with respect to the carbon nanotube 212 or 213, in such a manner that only those subregions of the material 214 to be patterned which are in the shadow of the carbon nanotubes 212, 213 with respect to the etchant are protected from removal as a result of etching.

The carbon nanotubes 212, 213 evidently serve as a mask, which mask determines which regions of the material 214 to be patterned are removed. On account of the geometric conditions shown in FIG. 2B, the region 219 which is attacked by etchant is determined by presetting the etchant direction 220 and by the arrangement of the carbon nanotubes 212, 213. It is possible to select which regions of material 214 to be patterned are to be removed by setting the distance between adjacent carbon nanotubes 212, 213, by setting the height of that region of the carbon nanotubes 212, 213 which projects out of the substrate 211 and by selecting the arrangement and angle of incidence of the etchant feed device 218. According to the scenario shown in FIG. 2B, only regions of material 214 to be patterned which lie on the upper and right-hand edge regions, as seen in FIG. 2B, of the carbon nanotubes 212, 213 are removed. It should also be noted that on account of the selectivity of the etching process (i.e. of the etchant), in particular the third further layer, which partially covers the carbon nanotubes 212, 213, is protected from being removed as a result of the etching.

The following text, referring to FIG. 2C, describes a cross-sectional view 230 through the patterning arrangement 210 shown in FIG. 2B, taken on section line B-B as shown in FIG. 2B. In this context, it should be noted that FIG. 2B shows only two carbon nanotubes 212, 213, whereas the carbon nanotubes 231, 232 which are additionally shown in FIG. 2C are concealed in FIG. 2B. The third carbon nanotube 231 and the fourth carbon nanotube 232 are likewise surrounded by a further layer 233. As can be seen from FIG. 2C, the material 214 to be patterned on the surface of the substrate 211 has been patterned as a result of the directional, angle-dependent etching, so as to form strips running parallel to one another which can be used, for example, as a bit line or word line.

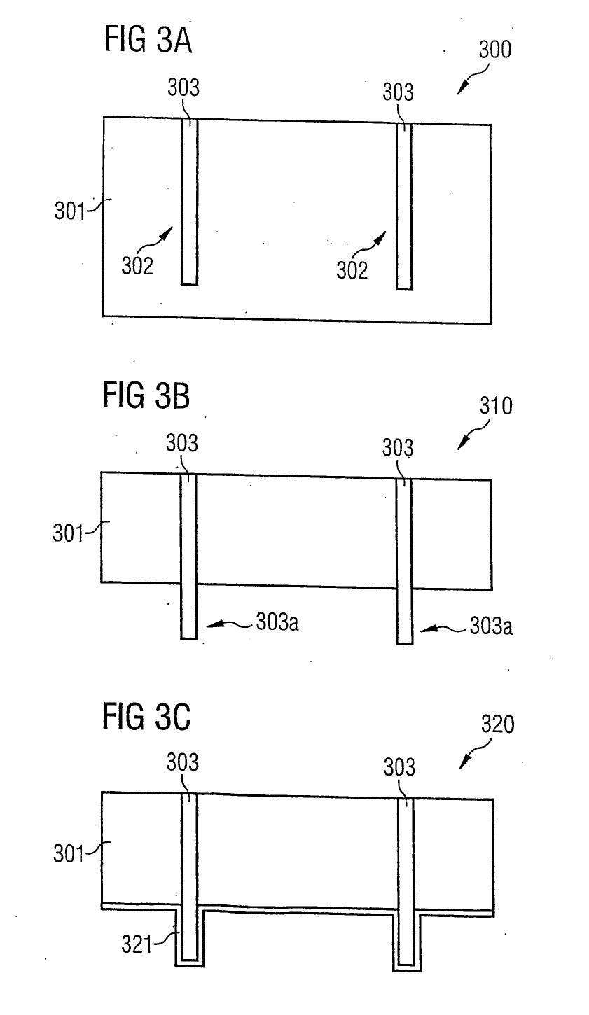

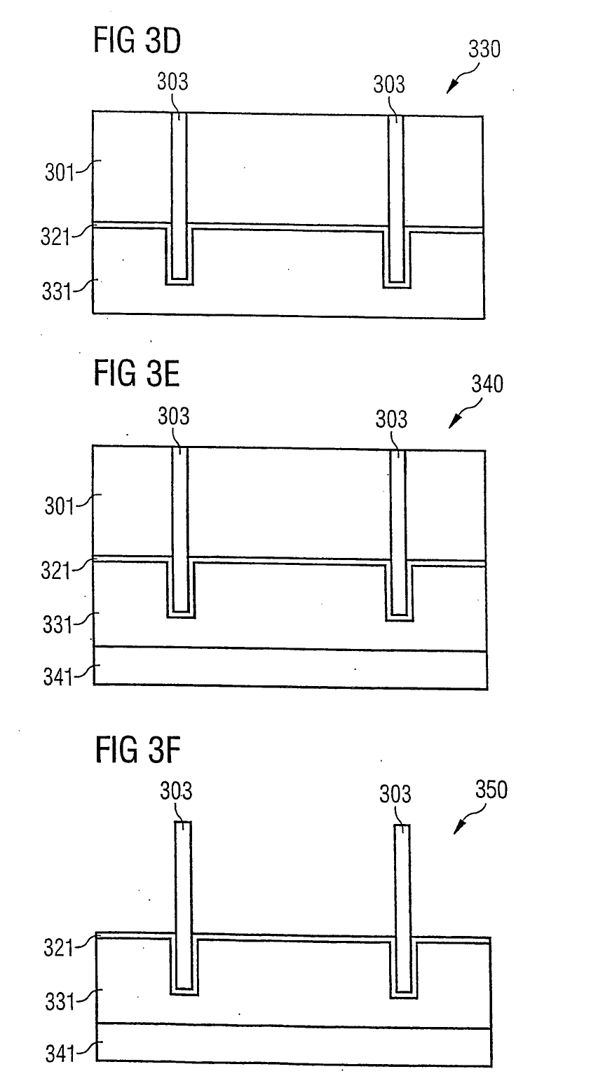

The following text refers to FIG. 3A to FIG. 3F to describe a method for fabricating a memory cell in accordance with a second preferred exemplary embodiment of the invention.

To obtain the layer sequence 300 shown in FIG. 3A, carbon nanotubes 303 are grown in an aluminum oxide substrate 301 with pores 302 formed therein in accordance with the method described in Suh et al. and Lee et al. The pores 302 in the aluminum oxide substrate 301 preferably form a square arrangement.

To obtain the layer sequence 310 shown in FIG. 3B, a lower region, as seen in FIG. 3B, of the aluminum oxide substrate 301 is removed using a suitable etching process, so that a first end portion 303a of the carbon nanotubes 303 is uncovered.

To obtain the layer sequence 320 shown in FIG. 3C, a dielectric layer 321 is deposited, using the CVD or ALD process, on the lower main surface, as seen in FIG. 3C, of the aluminum oxide substrate 301 and on that subregion of the carbon nanotubes 303 which is exposed outside the aluminum oxide substrate 301.

To obtain the layer sequence 330 shown in FIG. 3D, a polysilicon layer 331 is deposited on the lower surface, as seen in FIG. 3C, of the layer sequence 320, thereby forming one of the two electrically conductive elements of the subsequent storage capacitor. As an alternative to polysilicon material, it is also possible for a metal or a metal nitride (for example titanium nitride) to be used for the layer 331.

To obtain the layer sequence 340 shown in FIG. 3E, the layer sequence 340 is secured to a substrate 341, for example by wafer bonding.

To obtain the layer sequence 350 shown in FIG. 3F, the remaining region of the aluminum oxide substrate 301 is removed from the surface of the layer sequence 340 using a suitable etching process. This results in a layer sequence 350 which is similar to the layer sequence 119 from FIG. 1G. The further processing involved in forming a memory cell according to the invention starting from FIG. 3F can be realized using method steps as described starting from FIG. 1G through to FIG. 1O.

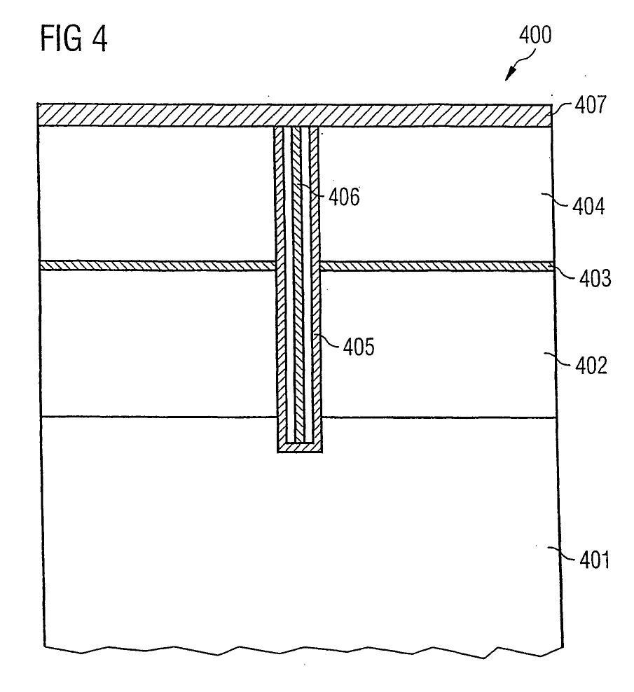

The following text refers to FIG. 4 to describe a memory cell 400 in accordance with another exemplary embodiment of the invention.

The memory cell 400 has a polycrystalline silicon substrate 401, on which a first silicon dioxide layer 402 has been formed. A thin first titanium nitride layer 403 has been applied to the first silicon dioxide layer 402. A second silicon dioxide layer 404 has been applied to the first titanium nitride layer 403. The layers 402 to 404 and a surface region of the silicon substrate 401 are subjected to a suitable etching process, so that a through-hole is etched through the layers 404 to 402, which through-hole extends all the way into a surface region of the silicon substrate 401. An electrically insulating third silicon dioxide layer 405 has been formed along the inner wall of the hole. A carbon nanotube 406 has been grown in the hole. A second titanium nitride layer 407 has been applied to the layer sequence obtained in this way.

In the memory cell 400, a region of the silicon substrate 401, as first electrically conductive capacitor element, a region of the third silicon dioxide layer 405, as capacitor dielectric, and a region of the carbon nanotube 406, as second electrically conductive capacitor element, form a storage capacitor.

Furthermore, a switching field-effect transistor is formed from a central region of the carbon nanotube 406 as channel region, a lower portion, as seen in FIG. 4, of the carbon nanotube 406 as first source/drain region, a boundary portion between the carbon nanotube 406 and the second titanium nitride layer 407 as second source/drain region and the first titanium nitride layer 403 as ring-like gate electrode. An electrical peak effect can be used to control the electrical conductivity of the carbon nanotube 406 particularly accurately in a surrounding region of the thin first titanium nitride layer 403 which surrounds the carbon nanotube in the form of a ring.

1. A memory cell, comprising:
a storage capacitor; and
a vertical switching transistor, which has a semiconducting nanostructure which has grown on at least part of the storage capacitor and includes a semiconducting nanotube, a bundle of semiconducting nanotubes, or a semiconducting nanorod.

2. The memory cell as claimed in claim 1, wherein the vertical switching transistor and the storage capacitor are formed at least partially in and/or at least partially on a substrate.

3. The memory cell as claimed in claim 2, wherein the nanostructure extends substantially orthogonally with respect to the surface of the substrate.

4. The memory cell as claimed in claim 3, wherein a first end portion of the nanostructure is arranged within the substrate and a second end portion of the nanostructure is arranged outside the substrate.

5. The memory cell as claimed in claim 1, wherein the vertical switching transistor is a field-effect transistor.

6. The memory cell as claimed in claim 5, wherein the first end portion of the nanostructure forms a first source/drain region of the vertical switching transistor, the second end portion of the nanostructure forms a second source/drain region of the vertical switching transistor, and an intermediate region of the nanostructure arranged between the two end portions forms a channel region of the vertical switching transistor.

7. The memory cell as claimed in claim 4, wherein a dielectric layer is formed between the first end portion of the nanostructure and the substrate, the first end portion of the nanostructure forming a first electrically conductive capacitor element of the storage capacitor, the dielectric layer forming a capacitor dielectric of the storage capacitor, and the substrate forming a second electrically conductive capacitor element of the storage capacitor.

8. The memory cell as claimed in claim 7, wherein a ferroelectric layer is formed instead of the dielectric layer.

9. The memory cell as claimed in claim 7, wherein catalyst material for catalyzing formation of the nanostructure is arranged between at least part of the dielectric layer and the nanostructure.

10. The memory cell as claimed in claim 6, wherein at least part of the intermediate region of the nanostructure is surrounded by an electrically insulating ring structure which forms the gate insulation layer of the vertical switching transistor, and
wherein at least part of the electrically insulating ring structure is surrounded by a first electrically conductive region which forms the gate electrode of the vertical switching transistor and the word line.

11. The memory cell as claimed in claim 4, wherein the second end portion of the nanostructure is surrounded by a second electrically conductive region, which forms the bit line.

12. The memory cell as claimed in claim 1, wherein the nanorod includes silicon, germanium, indium phosphide, and/or gallium arsenide.

13. The memory cell as claimed in claim 1, wherein the semiconducting nanotube is a semiconducting carbon nanotube, a semiconducting carbon-boron nanotube, or a semiconducting carbon-nitrogen nanotube.

14. The memory cell as claimed in claim 9, wherein the nanostructure is a carbon nanotube and the catalyst material includes iron, cobalt, and/or nickel.

15. The memory cell as claimed in claim 1, which is formed exclusively from dielectric material, metallic material, and the material of the nanostructure.

16. The memory cell as claimed in claim 2, wherein the substrate consists of polycrystalline, amorphous material or crystalline material.

17. A memory cell arrangement having a plurality of memory cells as claimed in claim 1.

18. A method for fabricating a memory cell, comprising the steps of:
forming a vertical switching transistor and a storage capacitor; and
forming a semiconducting nanostructure of the vertical switching transistor which has grown on at least part of the storage capacitor, the semiconducting nanostructure including a semiconducting nanotube, a bundle of semi conducting nanotubes, or a semiconducting nanorod.

19. The method as claimed in claim 18, wherein the vertical switching transistor and the storage capacitor are formed at least partially in and/or at least partially on a substrate.

20. The method as claimed in claim 19, wherein the nanostructure is formed substantially orthogonally with respect to the surface of the substrate.

21. The method as claimed in claim 19, wherein a first end portion of the nanostructure is formed within the substrate, and a second end portion of the nanostructure is formed outside the substrate.

22. The method as claimed in claim 21, wherein the first end portion of the nanostructure is formed as a first source/drain region of the vertical switching transistor, the second end portion of the nanostructure is formed as a second source/drain region of the vertical switching transistor, and an intermediate region of the nanostructure arranged between the two end portions is formed as a channel region of the vertical switching transistor, which is designed as a field-effect transistor.

23. The method as claimed in claim 21, further comprising the step of forming a dielectric layer between the first end portion of the nanostructure and the substrate, wherein the first end portion of the nanostructure is formed as a first electrically conductive capacitor element of the storage capacitor, the dielectric layer is formed as a capacitor dielectric of the storage capacitor, and the substrate is formed as a second electrically conductive capacitor element of the storage capacitor.

24. The method as claimed in claim 23, further comprising the step of forming catalyst material for catalyzing the formation of the nanostructure at least between part of the dielectric layer and the nanostructure.

25. The method as claimed in claim 22, wherein at least part of the intermediate region of the nanostructure is surrounded by an electrically insulating ring structure which forms the gate insulation layer of the vertical switching transistor, and
wherein at least part of the electrically insulating ring structure is surrounded by a first electrically conductive region which forms the gate electrode of the vertical switching transistor and the word line.

26. The method as claimed in claim 22, wherein the second end portion of the nanostructure is surrounded by a second electrically conductive region, which forms the bit line.

27. The method as claimed in claim 26, wherein the word line and/or the bit line and/or the gate electrode are formed by a method comprising the steps of:
covering a part of the nanostructure, which is uncovered or covered by a layer, with electrically conductive material; and
directing an etchant for etching the electrically conductive material onto the nanostructure covered with the electrically conductive material at a predetermined angle with respect to the nanostructure, in such a manner that only those subregions of the electrically conductive material which are in a shadow of the nanostructure with respect to the etchant are protected from being removed as a result of the etching.

28. A patterning arrangement comprising:
a nanostructure which extends substantially orthogonally with respect to a surface of a substrate and is arranged at least partially outside the substrate; and
material that is to be patterned on part of the nanostructure which is arranged outside the substrate, having an etchant feed device, which is designed in such a manner that it can be used to direct etchant for etching material that is to be patterned onto the nanostructure covered with material that is to be patterned at a predetermined angle with respect to the nanostructure, and in such a manner that only those subregions of the material to be patterned which are in a shadow of the nanostructure with respect to the etchant are protected from being removed as a result of the etching.

29. A system for fabricating a memory cell, comprising:
means for forming a vertical switching transistor and a storage capacitor; and
means for forming a semiconducting nanostructure of the vertical switching transistor which has grown on at least part of the storage capacitor, the semiconducting nanostructure including a semiconducting nanotube, a bundle of semiconducting nanotubes, or a semiconducting nanorod.

30. A method for fabricating a memory cell, comprising the steps of:
providing a substrate;
forming a trench in the substrate;
forming a dielectric later on the substrate and on the walls and bottom of the trench;
growing a nanostructure orthogonally with respect to the surface of the substrate such that a first end portion is arranged within the substrate and a second end portion is arranged outside the substrate;
covering the first end portion of the nanostructure and the exposed surface of the dielectric layer with electrically conductive material; and
directing an etchant for etching the electrically conductive material onto the nanostructure covered with the electrically conductive material at a predetermined angle with respect to the nanostructure, in such a manner that only those subregions of the electrically conductive material which are in a shadow of the nanostructure with respect to the etchant are protected from being removed as a result of the etching.

31. A method for fabricating a memory cell, comprising the steps of:
providing a first substrate;
forming pores in the first substrate;
growing nanostructures in the respective pores;
removing a lower region of the first substrate, such that first end portions of the nanostructures are uncovered;
depositing a dielectric layer on the lower surface of the first substrate and the exposed portions of the nanostructures;
depositing a polysilicon layer on the dielectric layer;
securing a second substrate to the polysilicon layer;
removing the remaining portion of the first substrate such that second end portions of the nanostructures are uncovered;
covering the second end portions of the nanostructures with electrically conductive material; and
directing an etchant for etching the electrically conductive material onto the nanostructure covered with the electrically conductive material at a predetermined angle with respect to the nanostructure, in such a manner that only those subregions of the electrically conductive material which are in a shadow of the nanostructure with respect to the etchant are protected from being removed as a result of the etching.

32. The method of claim 31, wherein the pores form a square arrangement.

33. A system for fabricating a memory cell, comprising:
a substrate;
means for forming a trench in the substrate;
means for forming a dielectric later on the substrate and on the walls and bottom of the trench;
means for growing a nanostructure orthogonally with respect to the surface of the substrate such that a first end portion is arranged within the substrate and a second end portion is arranged outside the substrate;
means for covering the first end portion of the nanostructure and the exposed surface of the dielectric layer with electrically conductive material; and
means for directing an etchant for etching the electrically conductive material onto the nanostructure covered with the electrically conductive material at a predetermined angle with respect to the nanostructure, in such a manner that only those subregions of the electrically conductive material which are in a shadow of the nanostructure with respect to the etchant are protected from being removed as a result of the etching.

34. A system for fabricating a memory cell, comprising:
a first substrate;
means for forming pores in the first substrate;
means for growing nanostructures in the respective pores;
means for removing a lower region of the first substrate, such that first end portions of the nanostructures are uncovered;
means for depositing a dielectric layer on the lower surface of the first substrate and the exposed portions of the nanostructures;
means for depositing a polysilicon layer on the dielectric layer;
means for securing a second substrate to the polysilicon layer;
means for removing the remaining portion of the first substrate such that second end portions of the nanostructures are uncovered;
means for covering the second end portions of the nanostructures with electrically conductive material; and
means for directing an etchant for etching the electrically conductive material onto the nanostructure covered with the electrically conductive material at a predetermined angle with respect to the nanostructure, in such a manner that only those subregions of the electrically conductive material which are in a shadow of the nanostructure with respect to the etchant are protected from being removed as a result of the etching.
